(19) United States
(12) Patent Application Publication
(10) Pub. No.: US 2016/0073517 A1
(43) Pub. Date: Mar. 10, 2016

(54) ELECTRONIC APPARATUS

(71) Applicant: MITSUBISHI ELECTRIC CORPORATION, Tokyo (JP)

(72) Inventor: Takahiro MUKADO, Tokyo (JP)

(73) Assignee: MITSUBISHI ELECTRIC CORPORATION, Tokyo (JP)

(21) Appl. No.: 14/787,429

(22) PCT Filed: Aug. 13, 2013
(86) PCT No.: PCT/JP2013/071877

§ 371 Date: Oct. 27, 2015

(51) Int. Cl. H05K 5/00

(52) U.S. Cl. CPC H05K 5/0008

(57) ABSTRACT

Provided is an electronic apparatus including recessed portions 3a-1 obtained by recessing corners of a side surface 3a of a housing 3 to the inner side of the housing 3, and lugs 3b-1 which are provided at the corners of a side surface 3b adjacent to the side surface 3a of the housing 3 provided with the recessed portions 3a-1, are bent toward. the recessed portions 3a-1, and are formed with screw-fixing holes 3b-2, wherein a cover 2 is disposed on the lugs 3b-1 and screw fixed to the screw fixing holes 3b-2.

### TECHNICAL FIELD

The present invention relates to an electronic apparatus having a structure in which a housing where an electronic circuit board is housed and a cover which covers the housing are fastened and fixed to each other.

### BACKGROUND ART

Conventionally, an electronic apparatus having the following structure is prevalent a housing for housing an electronic circuit board is covered with a cover, and the housing and cover are fastened to each other using a screw. In the screw fastening structure, the housing and cover are generally screw fastened to each other in a state in which the cover is disposed on a lug which is bent from an edge of the housing to the inner side of the housing.

In this structure, a screw tip is positioned inside the housing in the screw fastening, so that metal powder (chip) produced by friction between the screw and a screw hole easily enters the housing. Such metal powder may cause a malfunction of a sliding part in the housing and a short circuit in a high density board.

In order to solve the aforementioned problem, for example, in a housing described in Patent Document 1, a recessed portion obtained by recessing a part of a side surface of the housing to the inner side of the housing is formed by drawing or the like, a screw hole is provided in a part of the recessed portion, and a cap and a printed circuit board are disposed on and fixed to the part of the recessed portion using a screw. With this configuration, the screw tip is exposed on the recessed portion, namely, to the outside of the housing, thereby preventing the metal powder produced. in the screw fixing from entering the housing.

### CITATION LIST

### Patent Document

Patent Document 1: Japanese Translation of PCT Application No. 2007-534137

### SUMMARY OF THE INVENTION

### Problems to be Solved by the Invention

In the conventional technique represented by Patent Document 1, the part of the recessed portion formed in the housing is used as a mounting position of the cover. For this reason, there has been a problem that the height position of a mounting surface varies due to an effect of both the machining error of the recessed portion and the machining error in formation of a screw fixing portion, so that it is difficult to accomplish positional accuracy for forming the screw fixing portion.

The present invention has been achieved in order to solve the problem described above, and an object thereof is to obtain an electronic apparatus capable of improving positional accuracy for fixing the cover to the housing.

### Means for Solving the Problems

The electronic apparatus according to the present invention includes a box-like housing having one open side, a cover mounted to the housing so as to cover an opening of the housing, a recessed portion obtained by recessing a corner of a side surface of the opening of the housing to an inner side of the housing, and a lug provided at a corner of a side surface adjacent to the side surface of the housing provided with the recessed portion, bent toward the recessed portion, and formed with a screw fixing hole, and the cover is disposed on the lug and screw fixed to the screw fixing hole.

### Effect of the Invention

According to the present invention, there is an effect such that positional accuracy for fixing the cover to the housing can be improved.

### BRIEF DESCRIPTION OF THE DRAWINGS

FIG. 1 is a perspective view showing an electronic apparatus according to Embodiment 1 of the present invention.

FIG. 2 is an exploded perspective view of the electronic apparatus of FIG. 1.

FIG. 3 is a perspective view showing a screw fixing structure in Embodiment 1.

FIG. 4 is a view showing the configuration of the screw fixing structure on a housing side in Embodiment 1.

FIG. 5 is a side view showing the screw fixing structure in Embodiment 1.

FIG. 6 is a view showing another configuration of the screw fixing structure in Embodiment 1.

FIG. 7 is a view showing an example of a screw fixing hole.

### BEST MODE FOR CARRYING OUT THE INVENTION

Hereinafter, for illustrating the invention in more detail, embodiments for carrying out the invention will be described according to the accompanying drawings.

### Embodiment 1

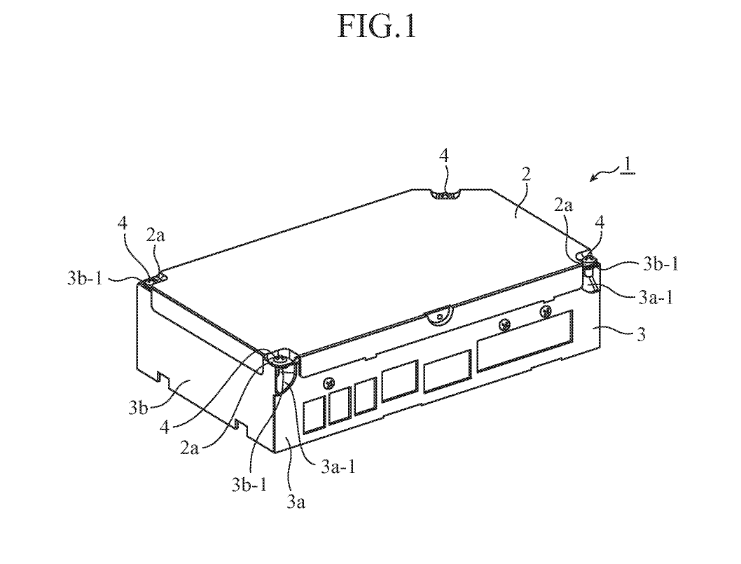

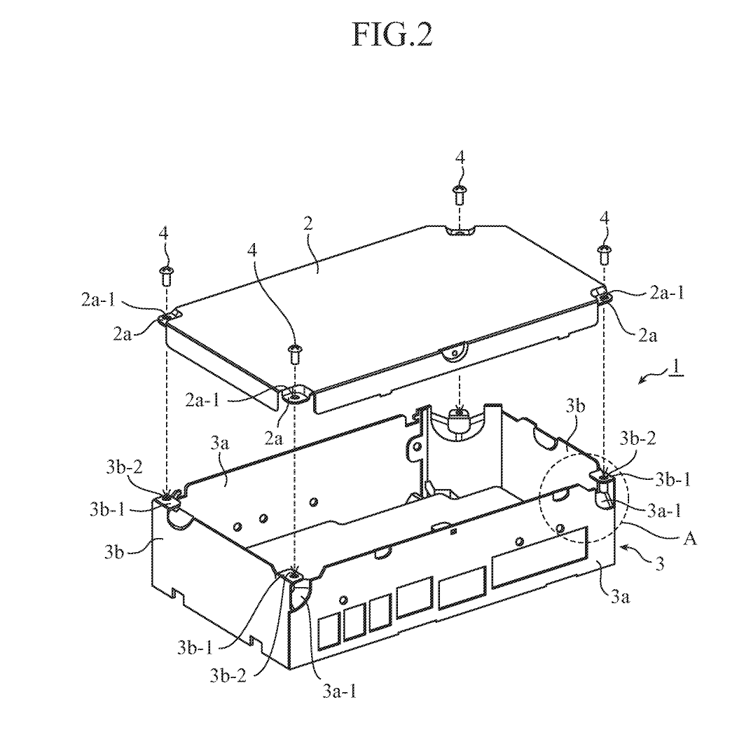

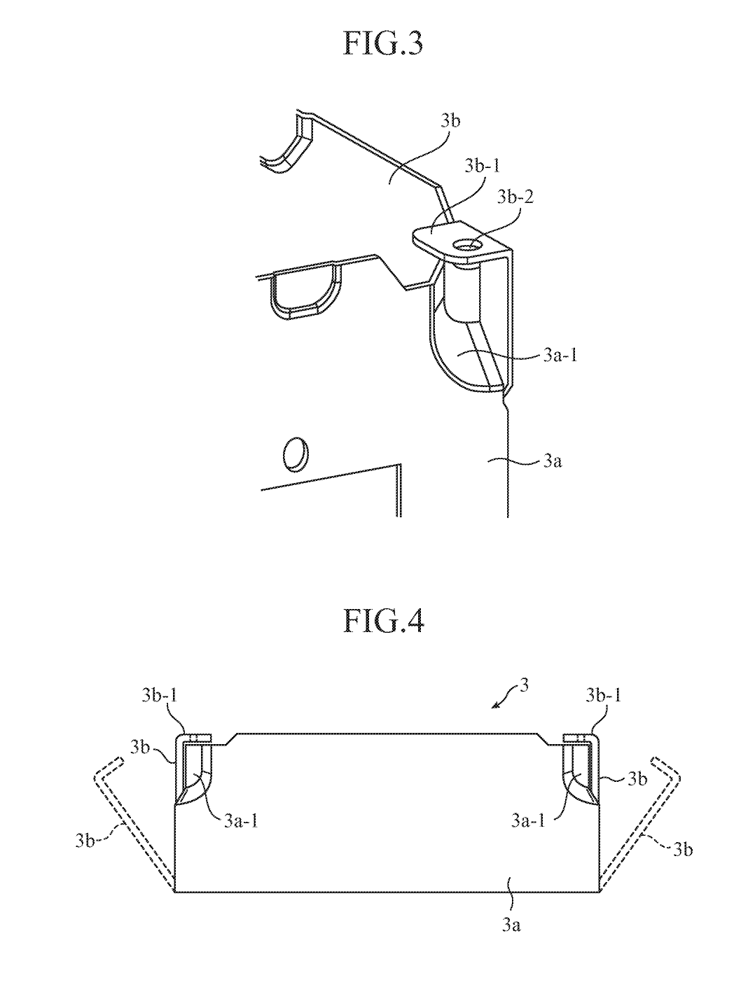

FIG. 1 is a perspective view showing an electronic apparatus according to Embodiment 1 of the present invention. FIG. 2 is an exploded perspective view of the electronic apparatus of FIG. 1. In addition, FIG. 3 is a perspective view showing a screw fixing structure in Embodiment 1, and is an enlarged view of a portion designated by a mark A in FIG. 2. An electronic apparatus 1 shown in FIG. 1 is, for example, an electronic apparatus mounted on a vehicle, and electronic components used for control of the vehicle etc. are housed in a space formed by mounting a cover 2 to a housing 3.

The cover 2 is a cover formed by, for example, pressing a metal plate material (sheet metal material), and is mounted to the housing 3 so as to cover an opening of the housing 3. In addition, as shown in FIG. 2, mounting portions 2a on which screw heads abut at the time of screw fixing are provided at four corners of the cover 2.

The mounting portion 2a is a recess obtained by recessing each of the four corners of the cover 2 more deeply relative to the height of the screw head, and a through hole 2a-1 for putting through a screw 4 is formed in a bottom surface of the recess

The housing 3 is formed by, for example, bending four sides of a sheet metal material by sheet metal working of a metal member (sheet metal material), and is a box-like housing which has the bent sides as side surfaces 3a and 3b, and one open side.

In addition, recessed portions 3a-1 configured by recessing corners of the side surfaces 3a to the inner side of the housing 3 are formed in the housing 3. For example, as shown in FIG. 3, each of the recessed portions 3a-1 is a drawn portion obtained by performing drawing such that the corner of the side surface 3a is recessed to the inner side of the housing 3.

Lugs 3b-1 are formed at the corners of the side surface 3b adjacent to the side surfaces 3a.

As shown in FIG. 3, the lug 3b-1 is a lug which is bent toward the recessed portion 3a-I in a direction parallel with a bottom surface of the housing 3 in addition, a screw fixing hole 3b-2 is also formed in the lug 3b-1, and the mounting portion 2a of the cover 2 is disposed on the lug 3b-1 at the time of the screw fixing.

When the mounting portion 2a of the cover 2 is disposed on the lug 3b-1 at the time of mounting the cover 2 to the housing 3, the through hole 2a-1 of the mounting portion 2a and the screw fixing hole 3b-2 of the lug 3b-1 are communicated with each other. With this, as shown in FIG. 2, the mounting portion 2a of the cover 2 is screw fixed to the screw fixing hole 3b-2 using the screw 4 which puts through the through hole 2a-1.

Note that, as shown in FIG. 3, she screw fixing hole 3b-2 is formed at a position which faces the recess of the recessed portion 3a-1 and does not allow the tip of the screw 4 to come in contact with the recessed portion 3a-1 at the time of the screw fixing. With this configuration, metal powder (chip) produced by friction between the screw 4 and the screw fixing hole 3b-2 falls to the outside of the housing 3 along the recessed portion 3a-1, so that no metal powder enters the housing 3.

In the conventional technique like Patent Document 1, the recessed portion is provided in the housing side surface or the like such that the screw tip after the screw fixing is positioned outside the housing, and the screw fixing hole is formed in a part of a circumferential surface configuring the recessed portion (a ledge in Patent Document 1). For this reason, there has been a problem that when the recessed portion is not machined precisely, the screw fixing position varies.

In contrast to this, as shown in FIG. 4, in the screw fixing structure of the electronic apparatus according to the present invention, the recessed portion 3a-1 for exposing the screw tip to the outside of the housing 3 is provided in the side surface 3a, and the lug 3b-1 for screw fixing the cover 2 is provided in the side surface 3b adjacent to the side surface 3a.

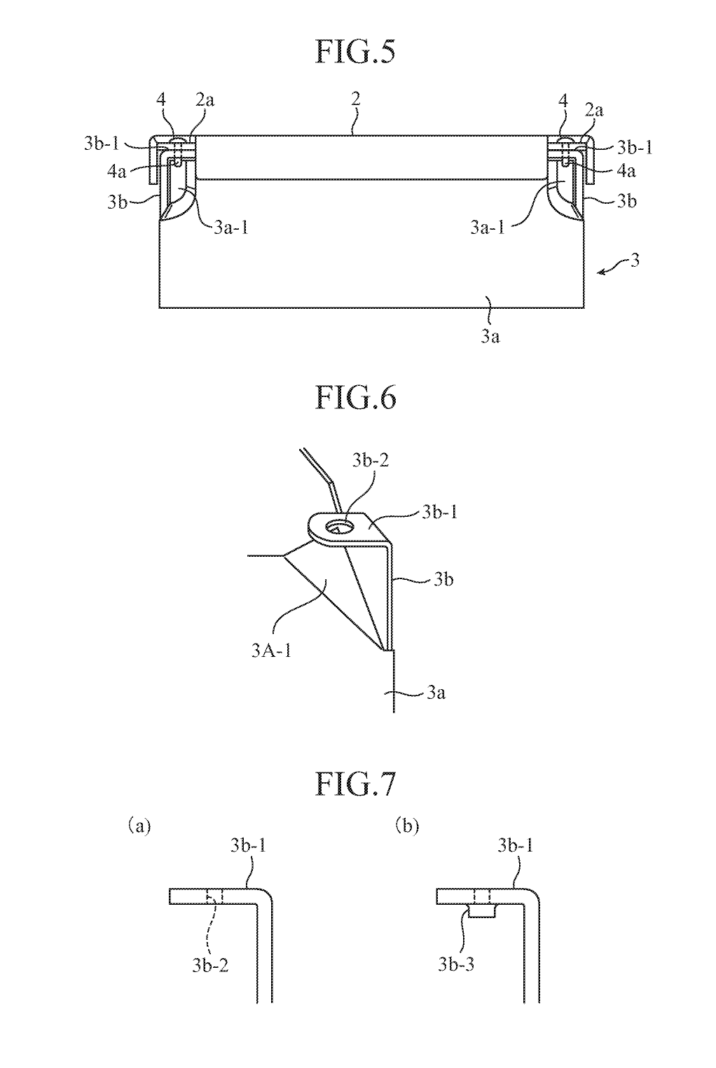

In addition, as shown in FIG. 5, the mounting portion 2a of the cover 2 is disposed on the lug 3b-1 and screw fixed thereto. At this point, with the recessed. portion 3a-1, a screw tip 4a of the screw 4 is positioned outside the housing 3. Thus, since the recessed portion 3a-1 is formed separately from the screw fixing hole 3b-2 of the lug 3b-1 serving as a screw fixing portion, positional accuracy of the screw fixing portion is not affected by the machining error of the recessed portion 3a-1, so that positional accuracy for fixing the cover 2 to the housing 3 can be improved as compared with the conventional structure.

In addition, FIG. 6 is a view showing another configuration of the screw fixing structure in Embodiment 1. A recessed portion 3A-1 shown in FIG. 6 is a bent portion obtained by bending she corner of the side surface 3a of the housing 3 to the inner side of the housing 3. With this configuration, it is also possible to expose the screw tip to the outside of the housing 3 at the time of the screw fixing, and prevent the metal powder produced by the friction between the screw 4 and the screw fixing hole 3b-2 from entering the housing 3. Besides, it can be formed by a process simpler than that of the recessed portion 3a-1 by the drawing.

Further, the screw fixing hole 3b-2 formed in the lug 3b-1 may be a hole for a female thread shown in FIG. 7(a) and, as shown in FIG. 7(b), it may be formed in a portion provided with a burring 3b-3 and protruding from the lug 3b-1.

In particular, when the screw fixing hole 3b-2 is formed in the portion provided with the burring 3b-3, it is possible to increase the length of screwing of the screw 4 as compared with the case where the screw hole is formed directly in the lug 3b-1, so that firm screw fixing is allowed.

Note that in the above description, there is shown the case where the lug 3b-1 is configured by being bent toward the recessed portion 3a-1 in the direction parallel with the bottom surface of the housing 3, but the invention is not limited thereto.

For example, the lug 3b-1 may be configured by being bent toward the recessed portion 3a-1 in a direction perpendicular to the bottom surface of the housing 3 (a direction parallel with the side surface 3a). In this case, it is conceivable that the mounting portion 2a of the cover 2 is formed at an end side portion of the cover 2 that is bent toward the side surface 3a, or formed at a lug that is extended from the end portion of the cover 2 and bent toward the side surface 3a so as to be disposed on the lug 3b-1 at the time of the screw fixing.

As described above, according to Embodiment 1, the housing 3 having one open side includes: the recessed portions 3a-1 which are obtained by recessing the corners of the side surface 3a of the opening of the housing 3 to the inner side of the housing 3; and the lugs 3b-1 which are provided at the corners of the side surface 3b adjacent to the side surface 3a of the housing 3 provided with the recessed portions 3a-1, bent toward the recessed portions 3a-1, and formed with the screw fixing holes 3b-2, and the cover 2 is disposed on the lugs 3a-1 so as to cover the opening of the housing 3 and screw fixed to the screw fixing holes 3b-2. Thus, since the recessed portion. 3a-1 is formed separately from the screw fixing hole 3b-2 of the lug 3b-1 serving as the screw fixing portion, the positional accuracy of the screw fixing portion is not affected by the machining error of the recessed portion 3a-1, so that the positional accuracy for fixing the cover 2 to the housing 3 can be improved as compared with the conventional structure.

In addition, according to Embodiment 1, the recessed 3a-1 is the drawn portion obtained by drawing the corner of the side. surface 3a of the housing 3 to the inner side of the housing 3. With this configuration, since the screw tip is exposed to the outside of the housing 3 at the time of the screw fixing, it is possible to prevent the metal powder produced by the friction between the screw 4 and screw fixing hole 3b-2 from entering the housing 3.

Further, according to Embodiment 1, the recessed portion 3A-1 is the bent portion obtained by bending the corner of the side surface 3a of the housing 3 to the inner side of the housing 3. With this configuration, it is possible to prevent the metal powder produced by the friction between the screw 4 and the screw fixing hole 3b-2 from entering the housing 3, and form the recessed portion 3A-1 by the process simpler than that of the recessed portion 3a-1 formed by the drawing.

Furthermore, according to Embodiment 1, since the screw fixing hole 3b-2 is formed in the portion provided with the burring 3b-3 and protruding from the lug 3b-1, it is possible to increase the length of screwing of the screw 4 as compared with the case where the screw hole is formed directly in the lug 3b-1, so that the firm, screw fixing is allowed.

Note that, in the present invention, a modification of any component of the embodiment or an omission of any component of the embodiment may be made within the scope of the invention.

### INDUSTRIAL APPLICABILITY

Since the electronic apparatus according to the present invention is capable of improving the positional accuracy for fixing the cover to the housing, it is suitable for an in-vehicle electronic apparatus which is disposed in a narrow space in a vehicle to require precise dimensional accuracy.

### DESCRIPTION OF REFERENCE NUMERALS AND SIGNS

1: electronic apparatus
2: cover
2a: mounting portion
2a-1: through hole
3: housing
3b: side surface
3a-1, 3A-1: recessed portion
3b-1: lug
3b-2: screw fixing hole
3b-3: burring
4: screw
4a: screw tip.

1. An electronic apparatus comprising:
a box-like housing having one open side;
a cover mounted to the housing so as to cover an opening of the housing;
a recessed portion obtained by recessing a corner of a side surface of the opening of the housing to an inner side of the housing; and
a lug provided at a corner of a side surface adjacent to the side surface of the housing provided with the recessed portion, bent toward the recessed portion, and formed with a screw fixing hole,
wherein the cover is disposed on the lug and screw fixed to the screw fixing hole.

2. The electronic apparatus according to claim 1, wherein
the recessed portion is a drawn portion obtained by drawing the corner of the side surface of the housing to the inner side of the housing.

3. The electronic apparatus according to claim 1, wherein
the recessed portion is a bent portion obtained by bending the corner of the side surface of the housing to the inner side of the housing.

4. The electronic apparatus according to claim 1, wherein
the screw fixing hole is formed in a portion subjected to burring and protruding from the lug.
